(19) United States
(12) Patent Application Publication
(10) Pub. No.: US 2023/0422400 A1
(43) Pub. Date: Dec. 28, 2023

(54) EMBEDDED MAGNETIC COMPONENT DEVICE INCLUDING VENTED CHANNEL AND MULTILAYER WINDINGS

(71) Applicant: Murata Manufacturing Co., Ltd., Nagaokakyo-shi, Kyoto-fu (JP)

(72) Inventors: Takayuki TANGE, Milton Keynes (GB); Neil STEPHENSON, Milton Keynes (GB); Lee FRANCIS, Milton Keynes (GB)

(21) Appl. No.: 18/035,614

(22) PCT Filed: Nov. 5, 2021
(86) PCT No.: PCT/US2021/058193

§ 371 Date: May 5, 2023

Related U.S. Application Data
(60) Provisional application No. 63/110,467, filed on Nov. 6, 2020.

(51) Int. Cl. H05K 1/16; H01F 27/26; H01F 27/28; H01F 41/04

(52) U.S. Cl. CPC H05K 1/165; H01F 27/266; H01F 27/2895; H01F 41/046; H01F 2027/2809; H01F 2027/2819; H05K 2201/086; H05K 3/4697

(57) ABSTRACT

A device includes a substrate including a cavity, a magnetic core in the cavity, a first winding extending around the magnetic core, and a single channel that extends between the cavity and an exterior of the device and that defines an opening. The first winding includes vias along an exterior periphery of the magnetic core opposite to the channel.

### BACKGROUND OF THE INVENTION

### 1. Field of the Invention

The present invention relates to embedded magnetic component devices. More specifically, the present invention relates to embedded magnetic component devices including a single vent channel and multilayer windings.

### 2. Description of the Related Art

Power supply devices, such as transformers and converters, include magnetic components such as transformer windings and often magnetic cores. The magnetic components typically contribute the most to the weight and size of the device, making miniaturization and cost reduction difficult.

In addressing this problem, it is known to provide low-profile transformers and inductors in which the magnetic components are embedded in a cavity in a resin substrate, and the input and output electrical connections of the transformer or inductor are formed on the substrate surface. A printed circuit board (PCB) of a power supply device can then be formed by adding layers of solder resist and copper plating to the top and/or the bottom surfaces of the substrate. The electronic components may then be surface mounted on the PCB. This allows a significantly more compact and thinner device to be built.

For example, a packaged structure having a magnetic component can be integrated into a PCB. In this structure, a cavity is formed in a substrate made of epoxy-based glass fiber, and a toroidal magnetic core is inserted into the cavity. The remaining space in the cavity is then filled with an epoxy gel so that the magnetic component is fully covered. The epoxy gel is then cured, forming a solid substrate with an embedded magnetic core.

Through holes used to form primary and secondary side transformer windings are then drilled in the substrate on the inside and outside circumferences of the toroidal magnetic component. The through holes are then plated with copper to form vias, and metallic traces are formed on the top and the bottom surfaces of the substrate to connect respective vias together into a winding configuration and to form input and output terminals. In this way, a coil conductor is created around the magnetic component. The coil conductor is included in an embedded transformer and has primary and secondary windings. An embedded inductor can be formed in the same or similar way but may vary in terms of the input and output connections, the spacing of the vias, and the type of magnetic core used.

Devices manufactured in this way have a number of associated problems. In particular, air bubbles may form in the epoxy gel as the epoxy gel solidifies. During reflow soldering of the electronic components on the surface of the substrate, these air bubbles can expand and cause failure of the device. Additionally, mechanical stresses introduced by differences between the coefficients of thermal expansion of the magnetic core, the epoxy gel, and the substrate can cause the magnetic core to crack.

To circumvent this problem, a device structure can be made in which epoxy gel is not used to fill the cavity, and an air gap is maintained between the magnetic core and the sides of the cavity. In this case, the spacing between the primary and the secondary windings must be large to achieve a high isolation value because the isolation is only limited by the dielectric strength of the air in the cavity or at the top and bottom surfaces of the device. The isolation value may also be adversely affected by contamination of the cavity or the surface with moisture and/or dirt.

To minimize contamination of the cavity, a circuit board package structure 100 of embedded magnetic component devices has been proposed in Taiwanese Patent Application TWM471030 where the cavity is vented to the exterior of the embedded magnetic component device. For example, FIG. 1 shows a mother substrate 110 that includes annular cavities 116, each including a circular magnetic component 130. As shown, the annular cavities 116 are connected to each other by channels or slots 118 in the direction D1. After magnetic components 130 are placed in the annular cavities 116, the mother substrate 110 is cut along line segments, e.g., lines L1-L4, to create individual device substrates having an area A1. Cutting the connecting channels 118 along line segments L1 and L2 creates an air path between the annular cavity 116 and the exterior of the individual device substrates as shown in FIG. 2.

FIG. 2 shows an example of an insulating substrate 301 of an individual embedded magnetic component device. As shown, the insulating substrate 301 includes a cavity 302 and two channels 303 formed between the circular cavity 302 and the exterior edges of the substrate 301. The channels 303 create openings or vents to allow air to flow between the cavity 302 and the exterior of the substrate 301. The presence of the channels 303 means that air can flow into and out of the cavity 302 during the subsequent stages of manufacturing of the embedded magnetic component device. As a result, there is a considerable reduction in the possibility of forming voids that can cause damage to the embedded magnetic component device during adhesive-curing and later reflow-soldering stages of manufacture. Furthermore, when the embedded magnetic component device is complete, the channels 303 and air gap in the cavity 302 aid with cooling of the embedded magnetic component device during operation.

However, an embedded magnetic component device formed using the substrate 301 shown in FIG. 2 has inherent problems. For example, FIG. 3 shows that the channels 303 reduce the area of the substrate that can be used to locate through holes or vias 411, 412, 421, 422 that connect metal traces 413, 423 of the primary and secondary windings 410 and 420. Increasing the amount of turns in a winding requires more through holes and may require that the substrate size be increased to accommodate the added area needed. Additionally, the substitution of air for insulating material of the substrate 301 necessary to form the channels 303 reduces the dielectric strength in the channel areas. With less dielectric strength against high voltage, the channels 303 of air can become a creepage path and a clearance path. The isolation value may also be adversely affected by contamination of the cavity or the surface with dirt. Therefore, more space may be required between the magnetic core 304 and the windings.

To meet the insulation requirements of EN/UL60950, an isolation distance of 0.4 mm is required through a solid insulator for mains referenced voltages (i.e., 250 Vrms), for example. FIG. 3 is a top view of an embedded magnetic component device with the upper winding layer exposed. The primary winding 410 of the transformer is shown on the left-hand side, and the secondary winding 420 of the transformer is shown on the right-hand side. In an isolated DC-DC converter, for example, the primary winding 410 and the secondary winding 420 of the transformer must be sufficiently isolated from one another. In FIG. 3, the central region of the substrate 305, the region circumscribed by the inner wall of the core cavity (shown by the concentric dotted circles) defines an isolation region 430 between the primary and the secondary windings 410 and 420. The minimum distance between the inner vias 412 and 422 of the primary and secondary windings 410 and 420 is the isolation distance and is illustrated in FIG. 3 by arrow 432.

However, the embedded magnetic component device shown in FIG. 3 has problems with coupling between the primary and secondary windings 410 and 420 and with a large leakage inductance. In operation, a large leakage inductance causes a voltage surge that can result in damage to connected circuitry, including the switching components. Additionally, leakage inductance causes a power transfer delay and poor load regulation when the circuit is operating at high frequency. The space inside the core is limited, and the device size would need to increase if more winding turns and corresponding through holes are needed, while maintaining the minimum isolation distance.

### SUMMARY OF THE INVENTION

To overcome the problems described above, preferred embodiments of the present invention provide embedded magnetic component devices with improved isolation characteristics. The embedded magnetic component devices can include one or more of the following features:
1) first and second electrical windings in which the first electrical winding is closer to the magnetic core than the second electrical winding;
2) a single vent channel with a bottom wall with an open recess adjacent to the channel opening;
3) a groove on the opposite side of the magnetic core defining the single vent channel;
4) a winding with vias along an exterior periphery of the magnetic core opposite to the single vent channel.
   Preferred embodiments of the present invention also provide methods of making such embedded magnetic component devices. Preferred embodiments of the present invention provide mother substrates from which the individual substrates of embedded magnetic component devices can be made and methods of making such individual substrates.

In a preferred embodiment of the present invention, an embedded magnetic component device includes an insulating substrate including a cavity and opposing first and second sides; a magnetic core in the cavity and including an inner periphery and an outer periphery; first and second electrical windings that extend through the insulating substrate and around the magnetic core, each of the first and the second electrical windings includes upper traces located on the first side of the insulating substrate; lower traces located on the second side of the insulating substrate; inner conductive connectors extending through the insulating substrate adjacent to the inner periphery of the magnetic core, the inner conductive connectors respectively defining electrical connections between respective upper traces and respective lower traces; and outer conductive connectors extending through the insulating substrate adjacent to the outer periphery of the magnetic core, the outer conductive connectors respectively define electrical connections between respective first upper traces and respective first lower traces, a top covering on the upper traces of the second electrical winding; a bottom covering on the lower traces of the second electrical winding; and a channel located in the insulating substrate and defining an opening connecting the cavity to an exterior of the insulated substrate. The first electrical winding is closer to the magnetic core than the second electrical winding.

The embedded magnetic component device can further include a layer of adhesive located on a floor of the cavity to secure the magnetic core in the cavity. The upper and the lower traces of the second electrical winding can be wider than the upper and the lower traces of the first electrical winding. The second electrical winding can overlap the first electrical winding.

The upper traces of the first electrical winding can be on a different layer of the insulating substrate than the upper traces of the second electrical winding, and the lower traces of the first electrical winding can be on a different layer than the upper traces of the second electrical winding.

The magnetic core can be octagonally shaped.

A first isolation layer can be located on the first side of the insulating substrate between the first electrical winding and the second electrical winding, and a second isolation layer can be located on the second side of the insulating substrate between the first electrical winding and the second electrical winding.

The first isolation layer and/or the second isolation layer can include a single layer.

A groove can be provided in the insulating substrate on a side opposite to that in which the channel is located.

In a preferred embodiment of the present invention, a method of manufacturing an embedded magnetic component device includes forming a cavity in an insulating substrate that includes a first side and a second side opposite to the first side; forming a channel between the cavity and an edge of the insulating substrate; installing a magnetic core in the cavity, the magnetic core including an inner periphery and an outer periphery; forming first and second electrical windings that extend through the insulating substrate and around the magnetic core, each of the first and the second electrical windings includes: upper traces located on the first side of the insulating substrate; lower traces located on the second side of the insulating substrate; inner conductive connectors extending through the insulating substrate adjacent to the inner periphery of the magnetic core, the inner conductive connectors respectively defining electrical connections between respective upper traces and respective lower traces; and outer conductive connectors extending through the insulating substrate adjacent to the outer periphery of the magnetic core, the outer conductive connectors respectively defining electrical connections between respective first upper traces and respective first lower conductive traces; forming a top covering on the upper traces of the second electrical winding; and forming a bottom covering on the lower traces of the second electrical winding. The first electrical winding is closer to the magnetic core than the second electrical winding.

The upper and the lower traces of the second electrical winding can be wider than the upper and the lower traces of the first electrical winding. The second electrical winding can include two outer conductive connectors between each respective first upper trace and respective first lower trace. The second electrical winding can overlap the first electrical winding.

The upper traces connected to the first electrical winding can be on a different layer than the upper traces connected to the second electrical winding, and the lower traces connected to the first electrical winding can be on a different layer than the lower traces connected to the second electrical winding.

A groove in the insulating substrate can be on a side opposite to that in which the channel is located. A portion of a bottom of the channel can be shorter than a top of the channel. A portion of a bottom of the groove can be shorter than a top of the groove. The channel can connect the cavity to an exterior of the embedded magnetic component device and the groove cannot.

In a preferred embodiment of the present invention, a device includes a substrate including a cavity; a magnetic core in the cavity; a first winding extending around the magnetic core; and a single channel that extends between the cavity and an exterior of the device, that defines an opening, and that includes a bottom wall with an open recess adjacent to the opening.

In a preferred embodiment of the present invention, a device includes a substrate including a cavity; a magnetic core in the cavity; a first winding extending around the magnetic core; a single channel that extends between the cavity and an exterior of the device and that defines an opening; and a groove that is located on an opposite side of the magnetic core as the single channel, that does not extend between the cavity and an exterior of the device, and that defines an opening.

Both the single channel and the groove can include a bottom wall with an open recess adjacent to the opening.

In preferred embodiment of the present invention, a device includes a substrate including a cavity; a magnetic core in the cavity; a first winding extending around the magnetic core; and a single channel that extends between the cavity and an exterior of the device and that defines an opening. The first winding includes vias along an exterior periphery of the magnetic core opposite to the channel.

The device can further include a second winding extending around the magnetic core and around a portion of the first winding; a first covering located on a first surface of the substrate and covering a first portion of the second winding; and a second covering located on a second surface of the substrate and covering a second portion of the second winding; wherein the first and the second windings can only extend around a same half of the magnetic core.

In preferred embodiment of the present invention, a module includes a device according to one of the other various preferred embodiments of the present invention, electronic components mounted on the first covering and/or the second covering, and a conformal coating or molding covering the electronic components.

The module can be a resonant converter with a resonant frequency determined by an overlap of the first and the second windings.

In a preferred embodiment of the present invention, a mother substrate includes a substrate; first and second cavities; first and second channels; first and second through holes. The first cavity is connected to a first end of the first channel and is not connected to any other channels; the first through hole is located at a second end of the first channel opposite to the first end; the second cavity is connected to a first end of the second channel and is not connected to any other channels; and the second through hole is located at a second end of the second channel opposite to the first end.

In a preferred embodiment of the present invention, a method of making device substrates includes providing a mother substrate; and dicing the mother substrate to provide first and second device substrates. The step of dicing includes dividing each of first and second through holes into first and second portions and dividing each of first and second channels into cavity-connected and not-connected portions. The first device substrate includes the cavity-connected portion of the first channel with the first portion of the first through hole and includes the not-connected portion of the second channel with the second portion of the second through hole. The second device substrate includes the cavity-connected portion of the second channel with the first portion of the second through hole and includes the not-connected portion of the first channel with the second portion of the first through hole.

The method can further include mounting circuit components to the mother substrate before the step of dicing.

In a preferred embodiment of the present invention, a mother substrate includes a substrate, first and second cavities, a single channel connecting the first and the second cavities, and a through hole in the single channel. The first and the second cavities are not connected to any other channels.

In a preferred embodiment of the present invention, a method of making device substrates includes providing the mother substrate according to one of the other various preferred embodiments of the present invention and dicing the mother substrate to provide first and second device substrates. The step of dicing includes dividing a through hole into first and second portions and dividing a single channel into first and second portions. The first device substrate includes the first portion of the through hole and the first portion of the single channel. The second device substrate includes the second portion of the through hole and the second portion of the single channel.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIGS. 1 and 2 show a configuration of a substrate for an embedded magnetic component device of the related art.

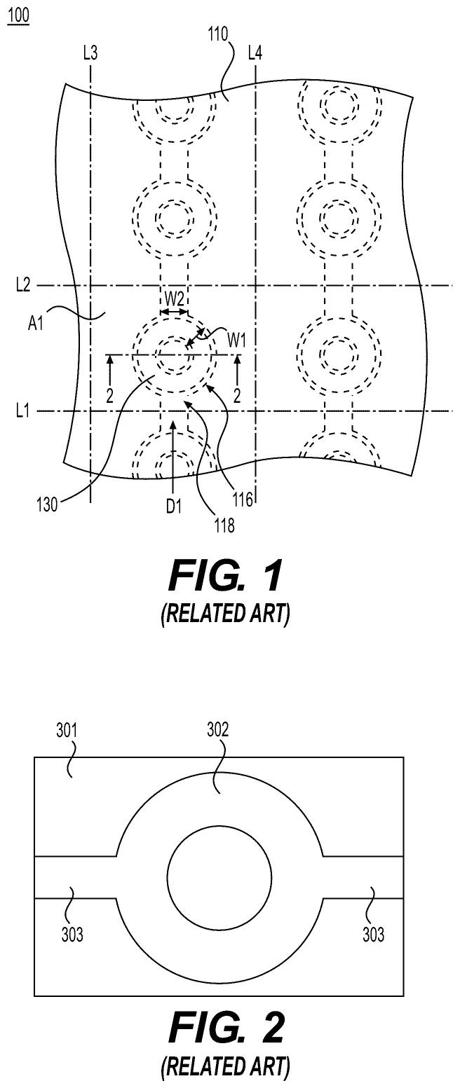

FIG. 3 shows a top down view of an embedded magnetic component of the related art.

FIG. 4A shows a plan view of an embedded magnetic component device with a single channel.

FIG. 4B shows a sectional view along line A-A of the embedded magnetic component device of FIG. 4A.

FIG. 5 shows a configuration of a mother substrate of an array of substrates with a single channel.

FIG. 6 shows an alternative configuration of a mother substrate of an array of substrates with a single channel.

FIGS. 7-10 show an embedded magnetic component device with windings wrapped around one side of a magnetic core.

FIGS. 11-13 show circuit modules with circuit components mounted on the top surface of the circuit modules.

FIG. 14 shows a circuit diagram of a DC-DC converter circuit that can include an embedded magnetic component device with a single channel.

### DETAILED DESCRIPTION OF THE PREFERRED EMBODIMENTS

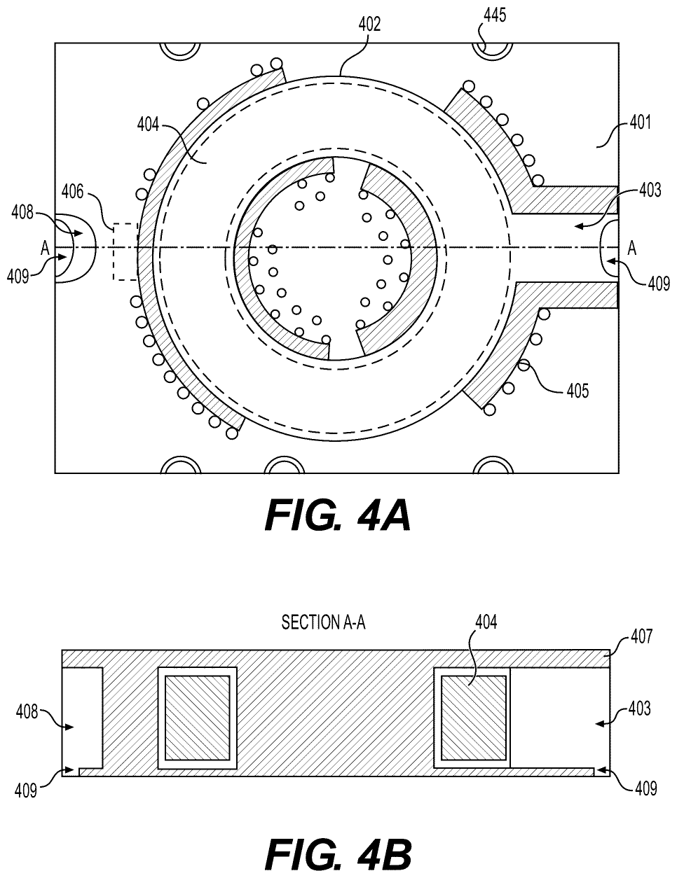

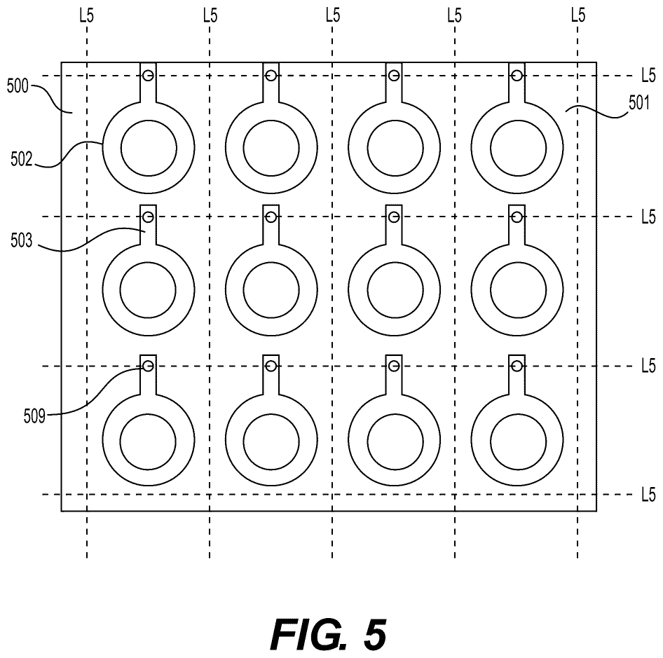

FIGS. 4A and 4B show that the embedded magnetic component device includes a substrate 401, a circular cavity 402, a channel 403 forming a vent between the cavity 402 and the exterior of the embedded magnetic component device, and a magnetic core 404 inside the cavity 402. The outline of the magnetic core 404 is represented with dashed lines in FIG. 4A. The smaller circles in FIG. 4A shows vias or conductive connectors 405 through the substrate 401 that can be metalized through holes that connect top and bottom conductive traces (not shown in FIG. 4A) that define portions of a winding or windings of the embedded magnetic component device. The embedded magnetic component device can include a transformer or an inductor, depending on the arrangement of the winding(s). The cross hatching in FIG. 4A represent keep-out areas where vias 405 should not be located. The keep-out areas provide a minimum distance between the magnetic core 404 and the vias 405 so that minimum creepage and clearances distances can be maintained between the magnetic core 404 and the vias 405. Although no vias 405 are shown within the dotted lined box 406, the area within the box 406 is available to locate vias 405 because there is no channel on the left side of the cavity 402. Thus, more vias and turns in a winding can be provided compared to the same area in a configuration of the related art that includes more than one channel.

The insulating substrate 401 can be formed of a resin material, such as FR4. FR4 is a composite ‘pre-preg’ material composed of woven fiberglass cloth impregnated with an epoxy resin binder. The resin is pre-dried, but not hardened, so that when the resin is heated, the resin flows and acts as an adhesive for the fiberglass material. FR4 has been found to have favorable thermal and insulation properties. A circular annulus or cavity 402 for housing the magnetic core 404 is routed or otherwise formed in the insulating substrate 401.

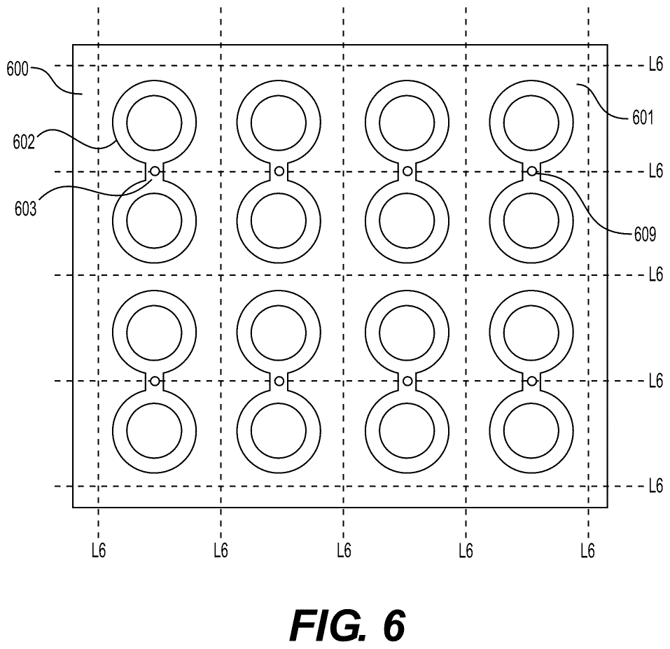

The cavity 402 includes only one channel 403 formed between the circular cavity 402 and the exterior edges of the substrate 401. The channel 403 can be formed by a router bit as the router bit begins and concludes the routing process of the circular cavity 402. That is, the router bit can enter and leave the substrate 401 via the same channel 403. Alternatively, the circular cavity 402 and channel 403 can be formed by building up resin layers in such a shape that the cavity 402 and channel 403 are formed. Optionally, castellations 445 can be included in the substrate 401. The bottom wall of the channel 403 can include a recess 409. As shown in FIG. 4A, the recess 409 can be open with walls along only portion of the periphery of the recess 409 and does not have to be a closed with walls along the entire periphery of the recess 409. The recess 409 can be formed when a mother substrate including through holes is diced, dividing the through holes, as discussed with respect to FIG. 5 below. The recess 409 can be formed from a single through hole as shown in FIG. 5 or from two or more through holes as shown in FIG. 13.

Adhesive can be applied to the base of the cavity 402 to secure the magnetic core 404 in place after the magnetic core 404 is inserted in the cavity 402. The cavity 402 can be slightly larger than the magnetic core 404, so that an air gap is maintained between the magnetic core 404 and sides of the cavity 402. The magnetic core 404 can be installed in the cavity manually or by a surface mounting device such as a pick-and-place machine. The magnetic core 404 can be located on the adhesive so that a secure bond is formed between the magnetic core 404 and an interior surface of the cavity 402. If the adhesive is a heat activated, a curing step of the adhesive can be carried out immediately, or later with the steps for forming subsequent insulating layers on the device.

FIG. 5 shows a mother substrate 500 with an array of substrates 501 with individual cavities 502 and channels 503. Line segments L5 (shown as horizontal and vertical dotted lines) indicate where the mother substrate 500 is to be cut to form the individual substrates 501. Additionally, a through hole 509 through the bottom of the channel 503 can be located in the channel 503. This through hole 509 allows moisture or any fluid to escape during processing. For example, any water or cleaning fluid in the channel 503 can be vaporized and allowed to escape during subsequent processes that include heating before dicing, such as when laminating the top cover over the cavities 502 and channels 503 or when soldering circuit components to the top and/or bottom surfaces. As further discussed below, circuitry components can be mounted to the top and/or bottom surfaces of the mother substrate 500 prior to dicing.

Because the through hole 509 can be in a high-voltage electrical path from the magnetic core to either a primary or a secondary circuit from adjacent circuitry, the through hole 509 can be located toward the exterior of the channel 503 away from the cavity 502. In the process of dicing along the line segments L5, the aligned through holes 509 in the mother substrate 500 can be divided into first and second portions, and the channel 503 can be divided into a connected portion that is connected to the cavity 502 and a non-connected portion that is not connected to the cavity 502. Each of the resulting individual substrates 501 includes a single cavity 502, the connected portion of one of channels 502 with a first portion of one of the divided through holes 509, and the non-connected portion of another channel 502 with a second portion of another one of the divided through holes.

Although FIG. 5 shows the channels 503 in the mother substrate before dicing, it is possible to add the channel 503 to each of the substrates 501 after dicing the mother substrate 500. The channel 503 can be added by routing, milling, cutting, or any other suitable method. It is also possible to provide a second channel (not shown) opposite of the channel 503 in the substrates 501. The second channel can be added to the mother substrate 500 before dicing or can be added to the substrates 501 after dicing.

Referring to FIG. 4B, after the magnetic core 404 is inserted into the cavity 402, an insulating layer 407 is secured or laminated on the substrate 401 to cover the cavity 402 and magnetic core 404. This insulating layer 407 can be made of the same material as the substrate 401, which aids in bonding between the top surface of the substrate 401 and the lower surface of the first insulating layer 407. Thus, this insulating layer 407 can be FR4 laminated onto the substrate 401. Lamination can be via adhesive or via heat activated bonding between layers of pre-preg material. Alternatively, other materials can be used for the insulating layer 407.

Dicing individual substrates that include a channel, a hole in the channel, and a covering insulating layer in this manner results in an embedded magnetic device with a cross section like that shown in FIG. 4B. On one side, the channel 403 exposes the magnetic core 404 to the exterior of the embedded magnetic component device and provides an air path for cooling. Opposite to the channel 403, the other side can have a groove 408 that does not extend to the cavity 402 but provides added surface area for cooling. This configuration also provides an area 406 in which through holes and vias 405 can be provided. As explained above, it is possible that the groove 408 can be replaced with a channel that extends from the magnetic core 404 to the exterior of the embedded magnetic component device.

In subsequent steps, the through holes for the vias 405 are made through the insulating substrate 401 and the insulating layer 407. The through holes are provided at suitable locations that can form via or conductive connections for the primary and secondary windings. As the embedded magnetic component device includes the magnetic core 404 that is round or circular in shape, the through holes are provided along sections of two arcs corresponding to inner and outer circular circumferences outside of the keep-out areas on inner and outer sides of the cavity 402. The through holes can be formed by drilling or another suitable technique. Drilling can include using a drill bit or laser, for example. Due to the presence of the channel 403, the through holes and subsequent vias 405 cannot be located at the 3 o'clock position around the cavity 402, as this would put holes in the channel 403 without continuous support from top to bottom of the substrate 401 required to form the vias 405. However, the 9 o'clock position within the area 406 is available in which to locate through holes and vias 405. An illustration of an example pattern of through holes used to form conductive vias 405 is shown in FIG. 4A.

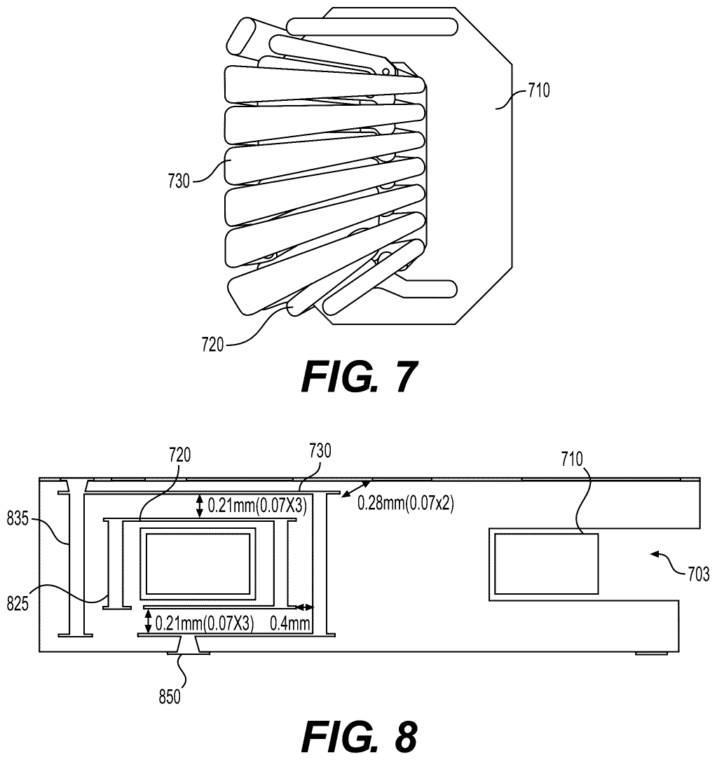

FIG. 6 shows a mother substrate 600 with an alternative array of substrates 601 with individual cavities 602, channels 603, and through holes 609 different from that shown in FIG. 5. Line segments L6 (shown by horizontal and vertical dotted lines) indicate where the mother substrate 600 is to be cut to form the individual substrates 601. As shown in FIG. 6, cavities 602 from two adjacent substrates 601 are connected by one channel 603 that has one through hole 609. Through hole 609 allows moisture or any fluid to escape during processing. For example, any water or cleaning fluid in the channel 603 can be vaporized and allowed to escape during subsequent processes that include heating before dicing, such as when laminating the top cover over the cavities 602 and channels 603 or when soldering circuit components to the top and/or bottom surfaces. As further discussed below, circuitry components can be mounted to the top and/or bottom surfaces of the mother substrate 600 prior to dicing. In the process of dicing along the line segments L6, the channels 603 and through holes 609 are bisected such that each individual substrate 601 will include one cavity 602 and a portion of the channel 603 and through hole 609. Individual substrates 601 made in this manner have the same advantages that those described with respect to FIGS. 4 and 5 and with the added advantage that there is more space to include through holes for vias on the opposite side of the channel 603 because there is no remaining portion of the channel in that location, as shown in FIG. 4B, after the hole 509 is bisected.

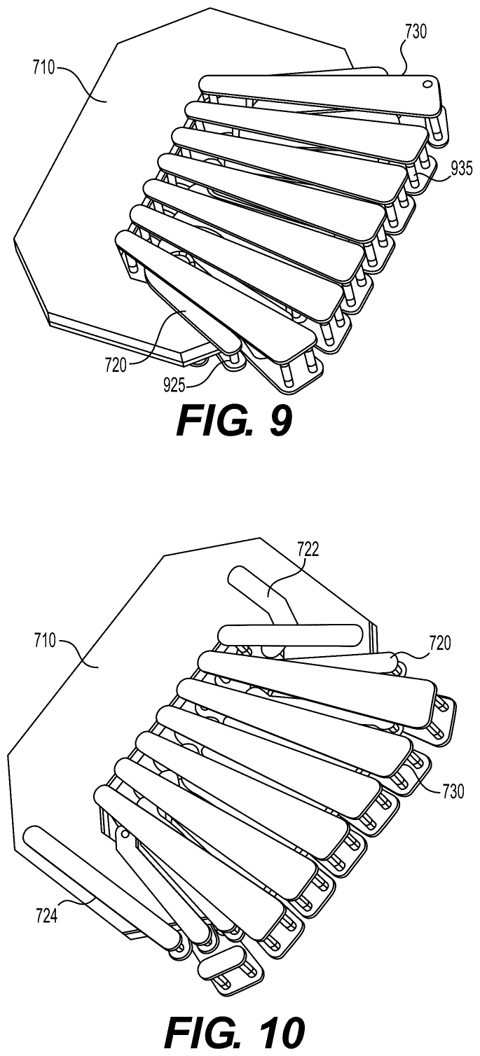

FIGS. 7-10 show an embedded magnetic component device with multilayer windings. The multilayer windings include a primary winding 720 and a secondary winding 730 wrapped around one side of a magnetic core 710.

FIG. 7 shows an embedded magnetic component device with multi-layer windings that includes a magnetic core 710, a primary winding 720, and a secondary winding 730 outside of the primary winding 720. The magnetic core 710 shown in FIG. 7 is octagonal shaped, but other shapes, including, for example, an elliptical shape, a rectangular shape can be used. If a shape with corners is used, then the corners can be sharp or rounded. For example, the magnetic core 710 can have an octagonal shape with rounded corners or can have rectangular shape with rounded corners. Each of the primary winding 720 and secondary windings 730 are defined by traces connected by vias. Although the secondary winding 730 is shown to be outside of the primary winding 720, the inner winding could be the secondary winding 730, and the outer winding could be the primary winding 720.

The primary winding 720 and the secondary winding 730 extend only around the same half of the magnetic core 710. As shown in FIGS. 7-10, it is possible that no turns of either the primary winding 720 or the secondary winding 730 extend around the other half of the magnetic core 710. The primary winding 720 and the secondary winding 730 can have any number of turns. In some applications, auxiliary windings (not shown) can extend around the same half of the magnetic core 710 around which the primary and the secondary windings 720 and 720 extend and/or the other half of the magnetic core 710 around which the primary and the secondary windings 720 and 720 do not extend.

The primary windings 720 can include two rows of inner vias in a hole extending through the magnetic core 710 and one row of outer vias on the exterior of the magnetic core 710. The secondary winding 730 can include one row of inner vias in the hole extending through the magnetic core 710 and one row of outer vias on the exterior of the magnetic core 710.

As shown in FIG. 7, the inner vias of the primary winding 720 and the secondary winding 730 can be arranged in three rows. But other arrangements are also possible.

As shown in FIG. 7, the row of outer vias of the primary windings 720 can be adjacent to and can extend along a portion of the periphery of the magnetic core 710. The row of outer vias of the secondary winding 730 can be adjacent to the row of outer vias of the primary winding 720 and spaced farther away from the magnetic core 710 than the row of outer vias of the primary winding 730. The outer vias of the primary winding 720 and the secondary winding 730 can extend along a portion of the periphery of the magnetic core 710 that is less than half of the total periphery of the magnetic core 710. For example, if the magnetic core 710 has an octagonal shape as shown in FIG. 7, then the outer vias of the primary winding 720 and the secondary winding 730 can extend along one, two, or three sides of the magnetic core 710. If the magnetic core 710 has a rectangular shape, then the outer vias of the primary winding 720 and the secondary winding 130 can extend along one side of the magnetic core 710.

The hole in the middle of the magnetic core 710 defining an inner periphery of the magnetic core 710 can have any suitable shape. For example, in FIG. 7, the inner and outer peripheries can both have the same octagonal shape. But the inner and outer peripheries can have different shapes.

As previously described, the magnetic core 710 can be installed within a cavity that can be formed in an insulating substrate. A first insulating layer can be secured or laminated on the top of the substrate to cover the cavity and the magnetic core 710. The first insulating layer can include a first metal layer that define traces of a portion of the primary winding 720, or the metal layer can be subsequently added. The bottom surface of the substrate can include a second metal layer that define traces of another portion of the primary winding 720, or the second metal layer can be subsequently added. Optionally, a second insulating layer and second metal layer can be secured to the bottom of the substrate.

Subsequently, a third insulating layer and a third metal layer can be secured or laminated on the top of the first insulating layer to define the traces of a portion of the secondary winding 730. A fourth insulating layer and a fourth metal layer can be secured or laminated on the bottom surface of the substrate or the second insulating layer to define the traces of another portion of the secondary winding 730.

As shown in FIG. 8, additional insulating layers can be used. For example, one or more additional insulating layers can be included between the substrate and the first insulating layer, one or more additional insulating layers can be included between the first insulating layer and the third insulating layer, one or more additional insulating layers can be included between the substrate and the second insulating layer, and one or more additional insulating layers can be included between the fourth insulating layer and either the substrate or the second insulating layer. Additionally, it is also possible to add additional insulating layers to the exterior of the device to cover any exposed metal layers. Covering exposed metal layers with additional insulating layers can reduce the creepage and clearance distances between the windings and any mounting members located on the exterior of the device.

The added insulating layers can be formed of the same material as the substrate to facilitate bonding between the top and the bottom surfaces of the substrate and the intermediate insulating layers. The added insulating layers can therefore be laminated onto the substrate and each other. Lamination may be performed by applying an adhesive or by performing heat activating bonding between layers of pre-preg material. The substrate and additional insulating layers can be FR4, G10, or any other suitable material. Alternatively, the added insulating layers and the substrate can include different materials.

FIG. 8 shows a side sectional view of the embedded magnetic component device shown in FIG. 7. FIG. 8 shows that vias 825 and 835 can be formed through the substrate and the additional insulating layers to connect the top and the bottom winding layers to each other. FIG. 8 shows the magnetic core 710, the primary winding 720, the secondary winding 730, vias 825 connecting the inner layers of the primary winding 720, and vias 835 connecting the outer layers of the secondary winding 730. FIG. 8 also shows a channel 703 that vents the cavity and magnetic core 710 to the exterior of the embedded magnetic component device.

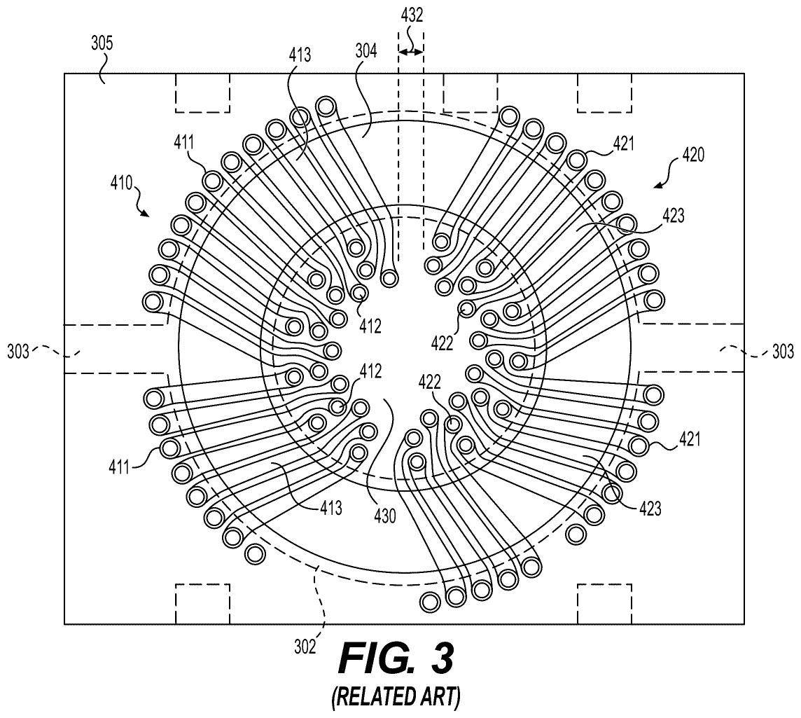

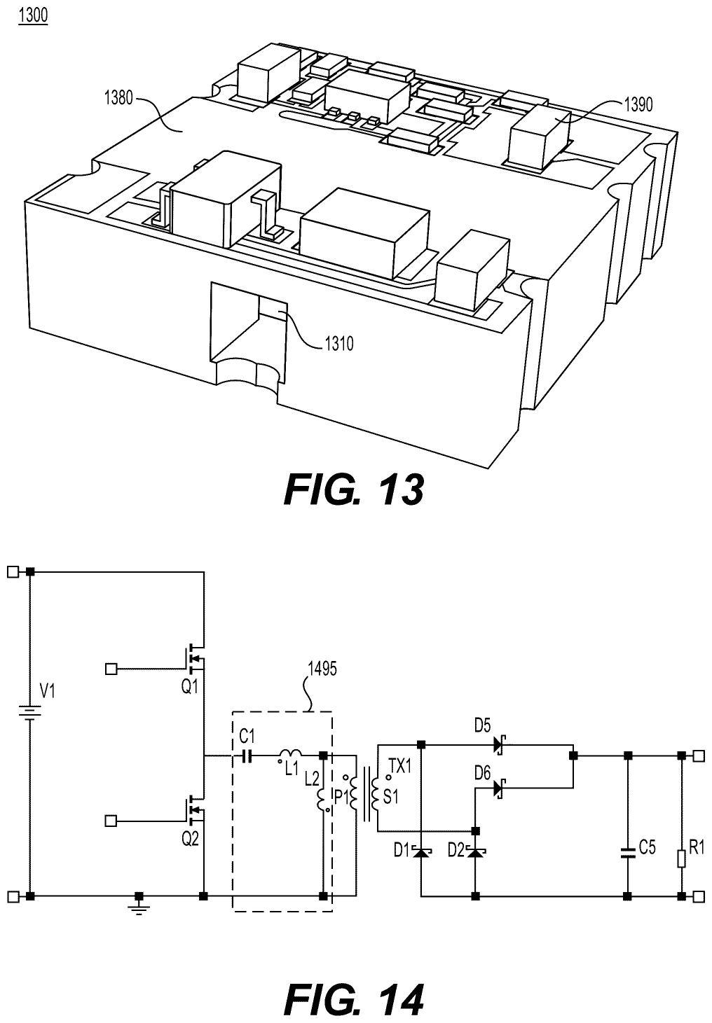

The magnetic core 710 can be a ferrite core as this provides the device with the desired inductance. Other types of magnetic materials, and air cores, that is an unfilled cavity formed between the windings, are also possible. Although, in the examples shown, the magnetic core 710 has an octagonal shape, it may have different shapes. The octagonal shape of the magnetic core 710 maximizes the magnetic space within the magnetic core for the induced magnetic field and the physical space for the vias 825 and 835. The magnetic core 710 can be coated with an insulating material to reduce the possibility of breakdown occurring between the conductive magnetic core 710 and the vias 825 and 835 or traces. This configuration of having the primary winding close to the secondary winding improves coupling, inductance, and resistance, while minimizing or decreasing the physical size. For example, the coupling can be improved from about 0.916 from the configuration shown in FIG. 3 to about 0.991 in the configuration shown in FIGS. 7-10. Additionally, leakage inductance, and thus the resonant frequency of a resonant converter such as the one shown in FIG. 14 that uses an embedded transformer, can be controlled by overlapping portions of the primary and secondary windings 720 and 730.

Additional winding(s) can be included on the other portion of the magnetic core 710 that does not include any windings. However, in this case, the physical size of the transformer would increase and the size of the opening through the magnetic core 710 would also need to increase to accommodate the additional necessary through holes.

FIG. 8 also indicates exemplary dimensions of distances between the layers of the inner and outer winding layers of about 0.28 mm or about 0.21 mm and a distance between the metal layers of the primary winding 720 and the vias 735 of the secondary winding 730 of about 0.4 mm. To meet the insulation requirements of EN/UL60950, 0.4 mm separation is required through a solid insulator for mains referenced voltages (250 Vrms), for example.

If the added insulating layers and the substrate are FR4, then FIG. 8 shows the primary windings 720 and secondary windings 730 can be vertically separated (i.e., the distance between adjacent traces of the primary windings 720 and secondary windings 730) by two insulation layers with a thickness of about 0.14 mm within manufacturing and measurement tolerances (i.e., a total of about 0.28 mm within manufacturing and measurement tolerances) or can be vertically separated by three insulation layers with a thickness of about 0.07 mm within manufacturing and measurement tolerances (i.e., a total of about 0.21 mm within manufacturing and measurement tolerances). FIG. 8 also shows that the primary windings 720 and the secondary windings 730 can be horizontally separated (i.e., the shortest distance between traces or vias of the primary winding and the vias of the secondary winding) by about 0.4 mm within manufacturing and measurement tolerances.

The IEC and UL safety standards require the distances between the electric windings to be more than 0.4 mm when the windings are integrated in the same layer of a substrate. In other rules of the IEC and UL standards, a dielectric “thin film sheet” is applied to the isolation that should be secured in the vertical direction. If the material used as the substrate has an isolation distance of 30 kV/mm, a minimum separation of 0.28 mm is required with two dielectric layers. With three dielectric layers, the minimum distance should be 0.21 mm. Accordingly, the isolation distances in the horizontal and vertical directions can be different from each other. The vias 825 and 835 are formed at suitable locations to form the primary and secondary windings 720 and 730. Because the transformer has a magnetic core 710 that is octagonal in shape with a corresponding octagonal-shaped opening in the center, the vias 825 and 835 are therefore suitably formed along portions of the opening and along one side of the outer circumference.

Through holes can be formed by any combination of drilling, etching, or any other suitable process or technique. The through holes can then be plated or otherwise metalized to form vias 825 and 835 that extend between the top and bottom traces of the corresponding primary and secondary windings 720 and 730.

Traces connecting the respective vias 825 and 835 define the primary and the secondary windings 720 and 730. The traces and the plating of the vias 825 and 835 are usually formed from copper, or other suitable metal or alloy, and can be formed in any suitable way, such as by adding a copper conductor layer to the outer surfaces of the insulating layer or substrate which is then etched to form the necessary patterns, depositing the copper onto the surface of the insulating layer or substrate, plating the copper onto the insulating layer or substrate, and so on. The width and shape of the traces forming the primary and the secondary windings 820 and 830 can be configured to reduce or minimize resistance. For example, as shown, the width of the traces forming the secondary winding 730 are wider toward the outside of the trace farthest from the opening through the magnetic core 710. Additionally, as shown, there can be two vias 835 used to connect traces defining the secondary winding 730 to reduce or minimize resistance of the longer secondary winding 730. Additional vias can be used to connect the same traces, depending on the width of the traces.

FIGS. 9 and 10 are respective top and bottom perspective views of the embedded magnetic component device of FIG. 7 shown without the materials of the substrate or insulating layers. FIGS. 9 and 10 show the magnetic core 710, the layers of the primary winding 720, the layers of the secondary winding 730, the vias 925 of the primary winding 720, and the vias 935 of the secondary winding. The bottom view of FIG. 10 shows that the primary 720 can include winding extensions 722 and 724 that can be used to locate and provide terminals 850 to connect the primary winding 720 to circuitry, as shown in FIG. 8.

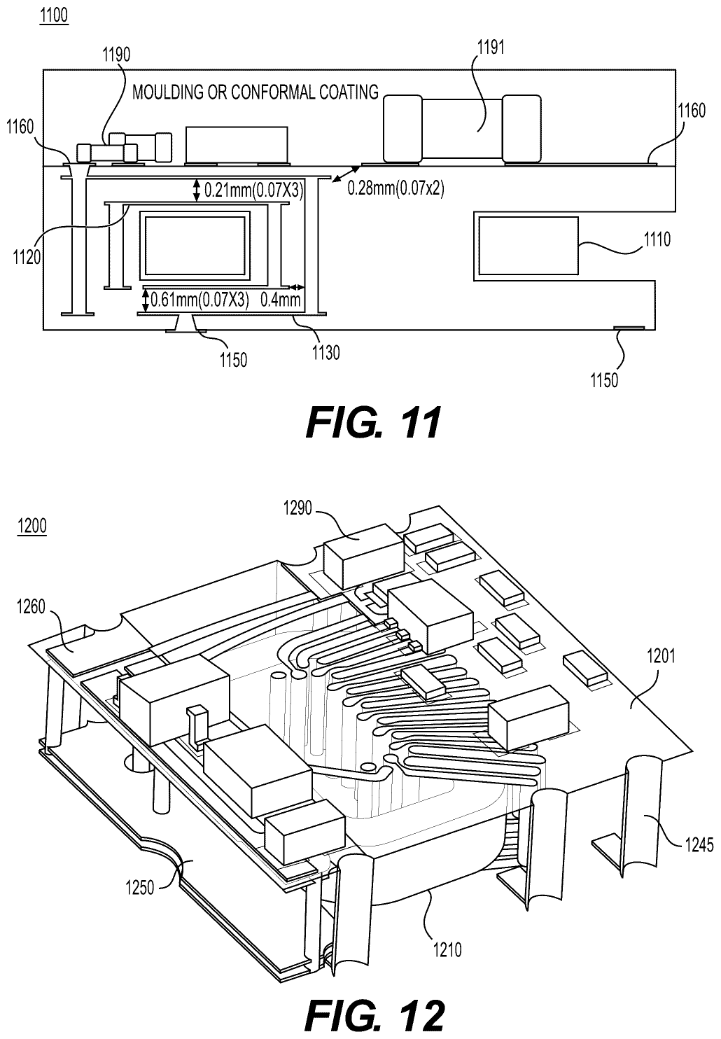

FIGS. 11-13 show circuit modules that include circuit components mounted to the top surface of the circuit modules. FIG. 11 is a side sectional view of a circuit module 1100 that includes an embedded transformer, FIG. 12 is a view of a circuit module 1200 with the insulating material of the substrate made transparent, and FIG. 13 is a perspective view of a circuit module 1300 with an embedded transformer where the embedded transformer cannot be seen.

FIG. 11 shows a circuit module 1100 with an embedded transformer including a core 1110, a primary winding 1120, a secondary winding 1130, and vias like those previously described. The circuit module 1100 also includes mounting members including top mounting members 1160 and bottom mounting members 1150. As shown, the bottom mounting members 1150 are pads like those shown in FIG. 8 that can be mounted to a substrate to electrically connect to other circuit components on the substrate. The top mounting members 1160 are shown as pads that are used to connect the embedded transformer to circuit components 1190 that are mounted on the top of the circuit module 1100.

The top covering, as previously described, allows additional circuit components 1190 to be mounted on the top surface of the circuit module 1100 to provide additional functionality. The circuit components 1190 can be mounted to the top surface before the mother substrate is diced. The additional circuit components 1190 can be encapsulated using any suitable encapsulant including a molding material or conformal coating. In FIG. 11, the circuit module 1100 includes secondary-side circuit components 1190 on the left side of the figure that are connected to the secondary winding 1130 and includes primary-side circuit components 1191 on the right side of FIG. 11 that are connected to the primary winding 1120. With layers of, for example, FR4 as the top covering on top of the embedded transformer, a distance of about 0.28 mm can be used between a top mounting member 1160 and the secondary winding 1130 when 4.2 kV isolation is required, for example.

A configuration with one air vent cavity structure allows conformal coating or molding to strengthen the primary-to-secondary isolation barrier. In cases where conformal coating is not applied, if there is more than one vent, then creepage distance needs to be considered as a distance from the primary circuit to the secondary circuit including the channel and the magnetic core. A configuration with only one channel achieves a comparatively significant size reduction.

FIG. 12 is a view of a circuit module 1200 with the insulating material of the substrate 1201 made transparent. Thus, the magnetic core 1210, metallization forming the windings, the bottom and top mounting members 1250 and 1260, and the castellations 1245, and magnetic core 1210 are visible. Circuit components 1290 that are mounted on the top of the circuit module 1200 are also shown.

FIG. 13 is a perspective view of a circuit module 1300 with an embedded transformer 1380 in which the windings and the magnetic core of the embedded transformer 1380 cannot be seen. FIG. 13 shows how circuit components 1390 can be mounted to one surface of the circuit module 1300. Circuit components 1390 can be mounted on one or both top and bottom surfaces of the circuit module 1300. Alternatively, the circuit components 1390 can be mounted on the bottom surface of the circuit module 1300, and the bottom mounting members can be posts such that circuit components 1390 are located on the circuit module 1300 between the embedded transformer 1380 and a substrate to which the circuit module 1300 is mounted. FIG. 13 also shows a channel that connects an internal cavity to the exterior of the circuit module 1300 in which a portion of a magnetic core 1310 can be seen.

FIG. 14 shows a schematic of a DC-DC converter circuit that can include an embedded magnetic component device. The DC-DC converter includes an input voltage V1; a switching stage including two transistors Q1 and Q2; a resonant tank 1495 including a resonant capacitor C1, a resonant inductor L1, and a magnetizing inductor L2; a transformer TX1 including a primary winding P1 and a secondary winding S1; a rectification stage including diodes D1, D2, D5, and D6 in a bridge arrangement; an output capacitor C5; and a resistor R1 representing the load. The transistors Q1, Q2 are connected in series and are connected to the input voltage V1. The resonant tank 1495 is connected between a node between the transistors Q1, Q2 and the transformer TX1. The resonant capacitor C1 and resonant inductor L1 can be connected in series but other arrangements are possible. The resonant inductor L1 can be the leakage inductance of the transformer TX1. The magnetizing inductor L2 is connected in parallel with the primary winding P1.

In the resonant topology shown in FIG. 14, the resonant inductance L1 can be adjusted to achieve the desired resonance frequency, which can be accomplished with a multi-layered embedded transformer implemented in the embedded magnetic component device shown FIGS. 7-10.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

1: An embedded magnetic component device comprising:
an insulating substrate including a cavity and opposing first and second sides;
a magnetic core in the cavity and including an inner periphery and an outer periphery;
first and second electrical windings that extend through the insulating substrate and around the magnetic core, each of the first and the second electrical windings including:
upper traces located on the first side of the insulating substrate;
lower traces located on the second side of the insulating substrate;
inner conductive connectors extending through the insulating substrate adjacent to the inner periphery of the magnetic core, the inner conductive connectors respectively defining electrical connections between respective upper traces and respective lower traces; and
outer conductive connectors extending through the insulating substrate adjacent to the outer periphery of the magnetic core, the outer conductive connectors respectively define electrical connections between respective first upper traces and respective first lower traces,
a top covering on the upper traces of the second electrical winding;
a bottom covering on the lower traces of the second electrical winding; and
a channel located in the insulating substrate and defining an opening connecting the cavity to an exterior of the insulating substrate, wherein
the first electrical winding is closer to the magnetic core than the second electrical winding.

2: The embedded magnetic component device of claim 1, further comprising a layer of adhesive located on a floor of the cavity to secure the magnetic core in the cavity.

3: The embedded magnetic component device of claim 1, wherein the upper and the lower traces of the second electrical winding are wider than the upper and the lower traces of the first electrical winding.

4: The embedded magnetic component device of any claim 1, wherein the second electrical winding overlaps the first electrical winding.

5: The embedded magnetic component device of claim 1, wherein
the upper traces of the first electrical winding are on a different layer of the insulating substrate than the upper traces of the second electrical winding, and
the lower traces of the first electrical winding are on a different layer of the insulating substrate than the upper traces of the second electrical winding.

6: The embedded magnetic component device of claim 1, wherein the magnetic core is octagonally shaped.

7: The embedded magnetic component device of claim 1, further comprising:
a first isolation layer located on the first side of the insulating substrate between the first electrical winding and the second electrical winding; and
a second isolation layer located on the second side of the insulating substrate between the first electrical winding and the second electrical winding.

8: The embedded magnetic component device of claim 7, wherein the first isolation layer and/or the second isolation layer include a single layer.

9: The embedded magnetic component device of claim 1, further comprising a groove in the insulating substrate on a side opposite to that in which the channel is located.

10: A method of manufacturing an embedded magnetic component device, the method comprising:
forming a cavity in an insulating substrate that includes a first side and a second side opposite to the first side;
forming a channel between the cavity and an edge of the insulating substrate;
installing a magnetic core in the cavity, the magnetic core including an inner periphery and an outer periphery;
forming first and second electrical windings that extend through the insulating substrate and around the magnetic core, each of the first and the second electrical windings including:
upper traces located on the first side of the insulating substrate;
lower traces located on the second side of the insulating substrate;
inner conductive connectors extending through the insulating substrate adjacent to the inner periphery of the magnetic core, the inner conductive connectors respectively defining electrical connections between respective upper traces and respective lower traces; and
outer conductive connectors extending through the insulating substrate adjacent to the outer periphery of the magnetic core, the outer conductive connectors respectively defining electrical connections between respective first upper traces and respective first lower conductive traces;
forming a top covering on the upper traces of the second electrical winding; and
forming a bottom covering on the lower traces of the second electrical winding, wherein
the first electrical winding is closer to the magnetic core than the second electrical winding.

11: The method of claim 10, wherein the upper and the lower traces of the second electrical winding are wider than the upper and the lower traces of the first electrical winding.

12: The method of claim 10, wherein the second electrical winding includes two outer conductive connectors between each respective first upper trace and respective first lower trace.

13: The method of claim 10, wherein the second electrical winding overlaps the first electrical winding.

14: The method of claim 10, wherein
the upper traces connected to the first electrical winding are on a different layer than the upper traces connected to the second electrical winding, and
the lower traces connected to the first electrical winding are on a different layer than the lower traces connected to the second electrical winding.

15: The method of claim 10, further comprising forming a groove in the insulating substrate on a side opposite to that in which the channel is located.

16: The method of claim 10, wherein a portion of a bottom of the channel is shorter than a top of the channel.

17: The method of claim 15, wherein a portion of a bottom of the groove is shorter than a top of the groove.

18: The method of claim 15, wherein the channel connects the cavity to an exterior of the embedded magnetic component device and the groove does not.

19: A device comprising:
a substrate including a cavity;
a magnetic core in the cavity;
a first winding extending around the magnetic core; and
a single channel that extends between the cavity and an exterior of the device, that defines an opening, and that includes a bottom wall with an open recess adjacent to the opening.

20: A device comprising:
a substrate including a cavity;
a magnetic core in the cavity;
a first winding extending around the magnetic core;
a single channel that extends between the cavity and an exterior of the device and that defines an opening; and
a groove that is located on an opposite side of the magnetic core as the single channel, that does not extend between the cavity and an exterior of the device, and that defines an opening.

21: The device of claim 20, wherein both the single channel and the groove include a bottom wall with an open recess adjacent to the opening.

22. (canceled)

23: A device comprising:
a substrate including a cavity;
a magnetic core in the cavity;
a first winding extending around the magnetic core;
a single channel that extends between the cavity and an exterior of the device and that defines an opening;
a second winding extending around the magnetic core and around a portion of the first winding;
a first covering located on a first surface of the substrate and covering a first portion of the second winding; and
a second covering located on a second surface of the substrate and covering a second portion of the second winding; wherein
the first winding includes vias along an exterior periphery of the magnetic core opposite to the single channel; and
the first and the second windings only extend around a same half of the magnetic core.

24: A module comprising:
the device of claim 23;
electronic components mounted on the first covering and/or the second covering; and
a conformal coating or molding covering the electronic components.

25: The module of claim 24, wherein the module is a resonant converter with a resonant frequency determined by an overlap of the first and the second windings.

26. (canceled)

27: A method of making device substrates, the method comprising:
providing a mother substrate comprising:
a substrate;
first and second cavities;
first and second channels; and
first and second through holes; and
dicing the mother substrate to provide first and second device substrates; wherein
the first cavity is connected to a first end of the first channel and is not connected to any other channels;
the first through hole is located at a second end of the first channel opposite to the first end;
the second cavity is connected to a first end of the second channel and is not connected to any other channels;
the second through hole is located at a second end of the second channel opposite to the first end;
the step of dicing includes dividing each of the first and the second through holes into first and second portions and dividing each of the first and the second channels into cavity-connected and not-connected portions;
the first device substrate includes the cavity-connected portion of the first channel with the first portion of the first through hole and includes the not-connected portion of the second channel with the second portion of the second through hole; and
the second device substrate includes the cavity-connected portion of the second channel with the first portion of the second through hole and includes the not-connected portion of the first channel with the second portion of the first through hole.

28: The method of making device substrates according to claim 27, further comprising mounting circuit components to the mother substrate before the step of dicing.

29. (canceled)

30: A method of making device substrates, the method comprising:
providing a mother substrate of comprising:
a substrate;
first and second cavities;
a single channel connecting the first and the second cavities; and
a through hole in the single channel; and
dicing the mother substrate to provide first and second device substrates; wherein
the first and the second cavities are not connected to any other channels;
the step of dicing includes dividing the through hole into first and second portions and dividing the single channel into first and second portions;
the first device substrate includes the first portion of the through hole and the first portion of the single channel; and
the second device substrate includes the second portion of the through hole and the second portion of the single channel.
